(19) United States
(12) Patent Application Publication
(10) Pub. No.: US 2025/0347366 A1
(43) Pub. Date: Nov. 13, 2025

(54) DESIGN METHOD FOR MULTI-DISC QUICK COUPLER AND MULTI-DISC QUICK COUPLER

(71) Applicant: SHANGHAI VISION MECHANICAL JOINT CO., LTD, Shanghai (CN)

(72) Inventors: Zhigang LU, Shanghai (CN); Xubin LU, Shanghai (CN); Zhibing ZHAI, Shanghai (CN); Jun WU, Shanghai (CN); Xin PENG, Shanghai (CN)

(21) Appl. No.: 18/926,445

(22) Filed: Oct. 25, 2024

(30) Foreign Application Priority Data
May 11, 2024 (CN) 202410582914.7

(51) Int. Cl. F16L 19/00; G06F 30/17

(52) U.S. Cl. CPC F16L 19/00; G06F 30/17

(57) ABSTRACT

A multi-disc quick coupler includes a clamp, a bolt connector and an articulated connector, the clamp includes at least three arc-shaped discs, the clamp is of an axisymmetric structure, and the articulated connector or the bolt connector is mounted between adjacent arc-shaped discs to connect them. The articulated connector includes rotary parts fixed to the arc-shaped disc and a connecting part hinged with the rotary parts, two rotary parts are provided corresponding to the adjacent arc-shaped discs, two ends of the connecting part are respectively rotatably connected to the two rotary parts. The design method therefor includes S1: determining a basic design size; S2: formulating design variables; S3: establishing a Cartesian coordinate system; S4: establishing a polar coordinate system; S5: calculating coordinates after rotation; S6: calculating the minimum value of Δθ; S7: deriving, by the computer, a curve of Δθ with design variables.

### CROSS-REFERENCE TO RELATED APPLICATION

This application claims the priority to Chinese patent application serial no. 202410582914.7, filed on May 11, 2024. The entirety of Chinese patent application serial no. 202410582914.7 is hereby incorporated by reference herein and made a part of this specification.

### TECHNICAL FIELD

The present application relates to the field of adapting pipe couplers, and more particularly, to a design method for a multi-disc quick coupler and a multi-disc quick coupler.

### BACKGROUND ART

At ordinary production, to save time and effort when connecting and mounting pipelines and pipes, it is common to use a coupler which may be quickly installed, i.e., a quick coupler. By a conventional quick coupler, a separate union or ring is clamped around a pipe end. The connection is so achieved, that the local radius of curvature of the housing itself is enlarged to deform the housing while mounting, such that the coupler key or slot is engaged with the groove, flange or clamp of the pipe (or to deform the housing, such that the serrations at the coupler key are meshed with the outer surface of the plain end pipe in an embedded manner). The separate pipe sleeve or ring is typically attached and fixed by means of attachment bolts, or attached by means of hinges at one end and attachment bolts at the other end.

In the existing art, to improve the installation efficiency of a pipeline, attachment bolts and nuts are generally pre-mounted on separate unions or rings, so as to save the process of inserting attachment bolts and screwing nuts on site. In use, firstly, the nut is screwed to the end of the attachment bolt, then the gap between the separated unions or rings is enlarged, to increase the inradius inside the housing of the quick coupler, so as to smoothly sleeve the quick coupler over the pipes to be connected, and then the nut is screwed and tightened, so as to clamp and hold the pipes with the separated unions or rings. However, to facilitate the screwing of the nut, such quick couplers are mostly screwed by a hexagon socket wrench, which realizes a very high screwing efficiency.

The maximum gap between the separate pipe sleeves or rings that may be enlarged is affected by a length size of the attachment bolts. To ensure that the pipe sleeve may be smoothly expanded until the pipe may be inserted, the attachment bolt needs to be provided with a relatively larger length. Conventional hexagon socket wrenches are often not deep enough to tighten the nuts for longer attachment bolts. To facilitate product sales, applicants often need to provide custom-made hexagon socket wrenches with great depth in the products of quick coupler, which greatly increases the product cost.

In view of the above-mentioned existing art, to reduce production costs, the applicant provides a design method for a multi-disc quick coupler and a multi-disc quick coupler, instead of merely adjusting the expansion gap of a pipe sleeve or ring by enlarging the length of an attachment bolt.

### SUMMARY

In a first aspect, the present application provides a design method for a multi-disc quick coupler, which adopts the following technical solutions.

A design method for a multi-disc quick coupler including a clamp, a bolt connector and an articulated connector, the clamp is configured as an annular coupler formed by jointing at least three arc-shaped discs, the clamp is of an axisymmetric structure as a whole, and the articulated connector or the bolt connector is mounted between adjacent arc-shaped discs of the at least three arc-shaped discs to connect the adjacent arc-shaped discs, the design method includes:
S1: determining a basic design size of the multi-disc quick coupler, the basic design size of the multi-disc quick coupler includes a diameter of an outer arc of the clamp A2, a diameter of an inner arc of the clamp A1, and a diameter of an outer arc of a pipe to be connected D1,
S2: formulating design variables including a radian of each of the at least three arc-shaped discs of the clamp and a position of each of rotation axes of the articulated connector, by which a specific angle, size or position parameter is formulated for each of the design variables according to design experiments;
S3: establishing a first Cartesian coordinate system, the first Cartesian coordinate system is established with a central symmetry axis of the clamp as a y-axis, an x-axis of the first Cartesian coordinate system passes through a first rotation axis of the rotation axes of the articulated connector at one side of the clamp away from the bolt connector, and coordinates of the first rotation axis of the rotation axes of the articulated connector and coordinates of endpoints of each of the at least three arc-shaped discs are calculated according to the basic design size of the multi-disc quick coupler and the design variables drawn up;
S4: establishing a first polar coordinate system, by which an origin of the first Cartesian coordinate system is moved to the first rotation axes of the articulated connector to form a first hinge point Cartesian coordinate system, so as to obtain first conversion functions between coordinates of point in the first hinge point Cartesian coordinate system and coordinates of point in the first Cartesian coordinate system, then the first polar coordinate system is established with the first rotation axes of the articulated connector as an origin, and second conversion functions between coordinates of point in the first polar coordinate system and the coordinates of point in the first hinge point Cartesian coordinate system are calculated,
S5: calculating coordinates after rotation, by which the first conversion functions and the second conversion functions are input into a mathematical calculation software, and polar coordinates of point after rotation are input into the mathematical calculation software, so that coordinates of point in the first Cartesian coordinate system after rotation are inversely calculated;
S6: calculating a minimum rotation angle, by which the minimum rotation angle is a rotation angle of the articulated connector, by which a diameter of an incircle of an inner arc of each of the at least three arc-shaped discs at endpoints is equal to the diameter of the outer arc of the pipe to be connected D1;
S7: verifying an influence of the design variables and determining the design variables, by which a value of a single one of the design variables is changed, the minimum rotation angle is calculated through the S6, function relationship curves of the minimum rotation angle with each of the design variables are obtained through loop calculation of the function calculation software, and a design variable value for effectively reducing the minimum rotation angle is selected.

By adopting the above-mentioned technical solution, the multi-disc quick coupler is placed in a coordinate system, so that the points at the inner arc of the arc-shaped disc may all be represented by the coordinates in each coordinate system, and in turn the function relationship for the coordinates change of the position during the rotation of the arc-shaped disc may be obtained, the changed coordinates may be conveniently obtained by using a mathematical function software, and then the minimum rotation angle of the arc-shaped disc may be calculated. When the rotation angle of the arc-shaped disc is minimum, the relative displacement of the two arc-shaped discs connected by the bolt connector is minimum, and the required bolt length is also minimum. Further, after a complete relationship function is obtained by inputting the formulated values of each design variable which affects the minimum rotation angle of the arc-shaped disc, the relationship between the minimum rotation angle and the corresponding variable may be obtained by adjusting the value of a single design variable to perform a loop calculation by using a mathematical function model software, so that the design variable value may be quickly selected. Finally, a quick coupler designed for a specific size of pipe may be obtained. On the premise of meeting the assembly requirements, the deformation of the quick coupler designed by this method is small and the length requirement of the attachment bolt is low, for which a conventional wrench may be used for assembly, which reduces the production cost of the quick coupler. Additionally, compared with the traditional two-disc quick coupler, the quick coupler designed by this method is more suitable to be assembled with the pipeline. After the quick coupler clamps the pipeline tightly, each arc-shaped disc exerts clamping force on the pipeline more evenly and the arc-shaped disc will not deform seriously, which allows the quick coupler to be disassembled and reused.

According to the present disclosure, the function relationships between each coordinates are calculated in sequence, the function relationships are input into the mathematical model software, and different design situations may be quickly verified with the help of the mathematical model software, which is helpful to improve the design efficiency, reduce the rotation angle of the arc-shaped disc to the maximum extent, and thus shortening the bolt length of the bolt connector as much as possible.

By the present application, the overall design calculation process is simplified by means of the axisymmetric structure of the clamp. Since the clamp is of an axisymmetric structure, the rotation angle of the arc-shaped disc is also symmetrical when the clamp is deformed to be expanded corresponding to the pipeline, thus only calculating the parameters of an arc-shaped disc on one side is sufficient, which simplifies the design process.

For a large pipe, the clamp needs to be provided with four or even more discs, and a plurality of articulated connectors needs to be provided. It is also possible to use the design scheme of the present application to calculate the minimum deformation parameter of the arc-shaped disc by establishing the change function of the coordinates of the endpoints of the inner arc of the arc-shaped disc, thereby shortening the required bolt length of the bolt connector and facilitating the mounting and use of the quick coupler.

In the present application, a bolt mounting hole on the ear plate is configured as a kidney-shaped hole, so that the requirement of increasing the bolt length caused by mutual displacement of adjacent arc-shaped discs may be eliminated. In addition, based on the logic of the present design method, i.e., eliminating the influence of the relative movement of the ear plates in the x-axis direction, the bolt length only needs to satisfy the requirements for the relative movement of the ear plates in the y-axis direction.

In a second aspect, the present application provides a disc quick coupler designed by the above-mentioned design method as follows.

A disc quick coupler includes the clamp, the bolt connector and the articulated connector, the clamp is configured as the annular coupler formed by jointing at least three arc-shaped discs, the clamp is of the axisymmetric structure as a whole, the articulated connector or the bolt connector is mounted between adjacent arc-shaped discs of the at least three arc-shaped discs to connect the adjacent arc-shaped discs, the bolt connector is configured to connect the adjacent arc-shaped discs, one of two ends of each of the at least three arc-shaped discs is provided with an ear plate for the bolt connector, the ear plate is configured with a kidney-shaped hole extending through the ear plate, an attachment bolt extends through the kidney-shaped hole, and a length direction of the kidney of the kidney-shaped hole is perpendicular to the central symmetry axis of the clamp.

The rotation connection structure formed by the latches and the snap ring according to the present application is flexibly assembled and disassembled, which is helpful for the efficient use of the quick coupler. The rotation connection structure formed by the latches and the snap ring has two rotation axes, such that the two adjacent arc-shaped discs may rotate more flexibly, and that the arc-shaped discs may better conform to the contour of the pipe to be connected, which is helpful for better reducing the overall deformation of the clamp, and may be more flexible during mounting, which is also helpful for shortening the length of the attachment bolt.

The articulated connector of the quick coupler of the present application is fixed with the clamp, which reduces the number of parts of the quick coupler, thereby facilitating the packaging, transportation and assembly.

The articulated connector at the end of the arc is of the same structure, may adopt the same mold structure, which facilitates the mold design and reduces the manufacturing cost.

In summary, the application has the following technical effects.

The present application provides a design method for a multi-disc quick coupler. Compared with a traditional two-disc quick coupler, the coupler is provided with at least three arc-shaped discs, so as to disperse the deformation amount to various directions of up, down, left and right by at least three arc-shaped discs, and the movement in the left and right directions is completed by the dislocation between a kidney-shaped hole or a U-shaped slot and an attachment bolt, and the remaining movement distance required in the length direction of the attachment bolt is much smaller, which effectively reduces the bolt length requirement of a bolt connector. In addition, by establishing a coordinate system based on the structure of the quick coupler, the rotation of the arc-shaped disc of the quick coupler is transformed into a mathematical function transformation, which facilitates the design calculation of the rotation process of the quick coupler. The relationship between the minimum rotation angle and each design variable may be obtained by using the mathematical function software, to select the most appropriate size to reduce the design requirements of the bolt length as far as possible, thereby reducing the requirements of the screwing tool. The conventional hexagon socket wrench may be used for screwing, which is convenient for operation and reduces the production cost.

### BRIEF DESCRIPTION OF THE DRAWINGS

FIG. 1 is a schematic view showing a three-disc double-bolt quick coupler according to an embodiment of the present application;

FIG. 2 a sectional view along A-A of FIG. 1;

FIG. 3 is a schematic diagram showing a pre-mounted state of a three-disc double-bolt quick coupler;

FIG. 4 is an exploded view of a three-disc double-bolt quick coupler;

FIG. 5 is a schematic view showing a Cartesian coordinate system with the structure of a three-disc double-bolt quick coupler;

FIG. 6 is a schematic diagram showing a Cartesian coordinate system with the structure of an open three-disc double-bolt quick coupler;

FIG. 7 is the relation curve of Δθ with T;

FIG. 8 is the relation curve of Δθ with θ1;

FIG. 9 is a schematic diagram showing offset angles of the inner and outer arcs of the arc discs;

FIG. 10 is a schematic view showing the deviation angle c with a transverse distance of the ends of the arc-shaped disc;

FIG. 11 is a schematic diagram showing the deviation angle c with a longitudinal distance of the ends of the arc-shaped disc;

FIG. 12 is a schematic view showing the overall structure according to Embodiment 2 of the present application;

FIG. 13 is a schematic view showing a first Cartesian coordinate system with the clamp of the quick coupler of Embodiment 2;

FIG. 14 is a schematic view showing the overall structure according to Embodiment 3 of the present application;

FIG. 15 is a schematic view showing the overall structure according to Embodiment 4 of the present application;

FIG. 16 is a schematic view showing the overall structure according to Embodiment 5 of the present application;

FIG. 17 is a schematic view showing the overall structure according to Embodiment 6 of the present application;

FIG. 18 is an exploded view of FIG. 17;

FIG. 19 is a first schematic view showing the overall structure according to Embodiment 7 of the present application;

FIG. 20 is a second schematic view showing the overall structure according to Embodiment 7 of the present application;

FIG. 21 is a schematic view showing the overall structure according to Embodiment 8 of the present application;

FIG. 22 is a schematic view showing the overall structure according to Embodiment 9 of the present application;

FIG. 23 is an exploded view of FIG. 22;

FIG. 24 is a schematic view showing the overall structure according to Embodiment 10 of the present application;

FIG. 25 is an exploded view of FIG. 24;

FIG. 26 is a schematic view showing a fitting relationship according to Embodiment 10 of the present application;

FIG. 27 is a first schematic view showing the overall structure according to Embodiment 11 of the present application;

FIG. 28 is a second schematic view showing the overall structure according to Embodiment 11 of the present application;

FIG. 29 is a schematic view showing the overall structure according to Embodiment 12 of the present application.

### DETAILED DESCRIPTION

The present application discloses a design method for a multi-disc quick coupler and a multi-disc quick coupler, which will be described in detail below with reference to specific embodiments.

### Embodiment 1

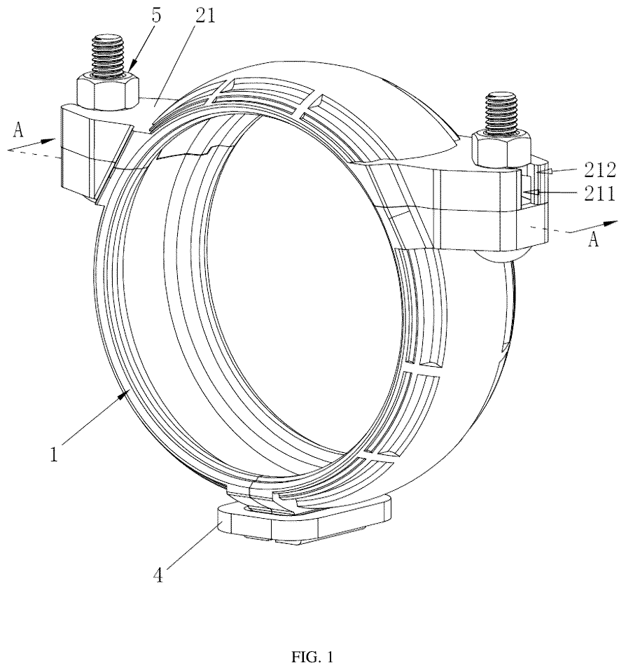

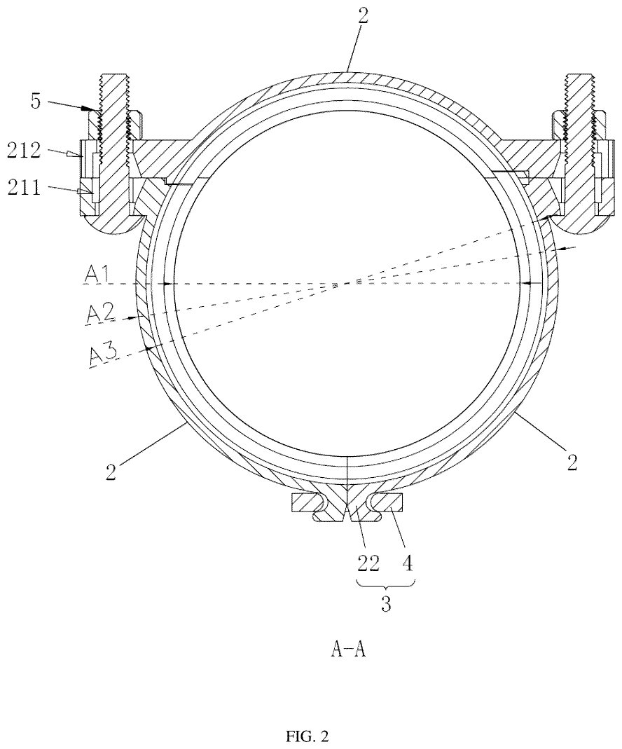

A three-disc double-bolt quick coupler, referring to FIGS. 1 and 2, includes an annular clamp 1 made up of three circular arc-shaped discs 2, an articulated connector 3 and bolt connectors 5 for connecting adjacent arc-shaped discs 2. One pair of three pairs of interfaces in the circumferential direction of the clamp 1 is rotationally connected with the articulated connector 3, while the other two pairs are connected by means of the bolt connectors 5. The end of the arc-shaped disc 2 is provided with an ear plate 21 for the bolt connector 5, and the pair of interfaces connected by the bolt connector 5 are perpendicular to the attachment bolt. The whole clamp 1 is axisymmetric.

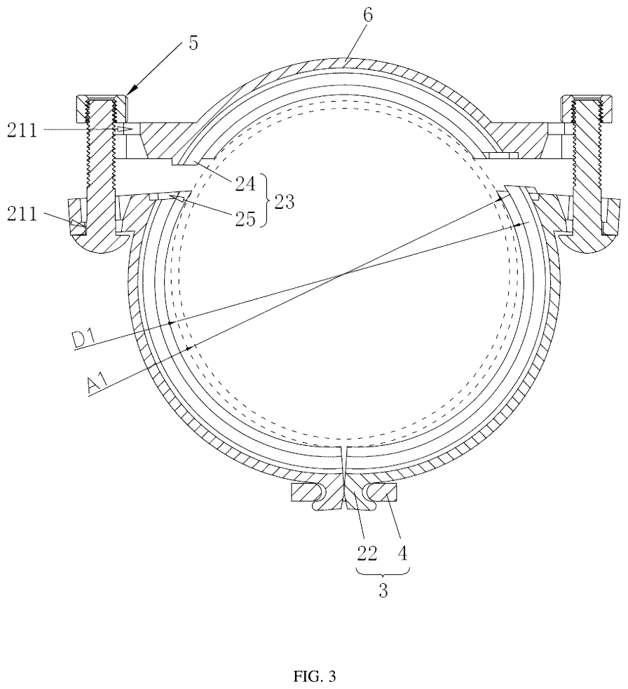

The articulated connector 3 includes rotary parts fixed at ends of the arc-shaped disc 2 and a connecting part configured for connecting two adjacent rotary parts, and two ends of the connecting part are respectively hinged to the two adjacent rotary parts. Referring to FIGS. 2 and 3, the rotary part is designed as a latch 22 in the shape of bent rod integrally formed at the end of the arc-shaped disc 2, and the connecting part is designed as an annular snap ring 4. After the ends of the arc-shaped discs 2 are jointed together, the snap ring 4 snaps the two jointed rotary parts together. The whole contour of the two rotary parts is arcs facing away from each other. The inner sidewall of the snap ring 4 is configured as an arc-shaped face. A certain fit clearance is left between the snap ring 4 and the two latches 22, and after the two latches 22 are inserted into the snap ring 4, the two rotary parts may rotate relative to each other, so that the included angle between the two adjacent arc-shaped discs 2 is enlarged.

Referring to FIGS. 3 and 4, the bolt connector 5 includes an attachment bolt and a nut, and the arc-shaped disc 2, whose two ends are fixed by bolt connectors 5, is a liftable section 6. The liftable section 6 does not rotate, and the mounting diameter of the quick coupler is enlarged mainly by lifting the liftable section along the bolt. The end of the arc-shaped disc 2 is integrally formed with an ear plate 21 for the bolt connector 5, the hole, through which the attachment bolt passes, is a kidney-shaped hole, and the length direction of the kidney of the kidney-shaped hole 211 is perpendicular to the central symmetry axis of the clamp 1, so that the bolt always remains parallel to the central symmetry axis of the clamp 1. The bolt length only needs to achieve the deformation range of the liftable section 6 in the vertical direction, which helps to reduce requirement for the bolt length. The ends of the two arc-shaped discs 2 connected with bolt connectors 5 are further provided with a plug-in unit 23 for plug-in connection, the plug-in unit 23 includes a plug-in block 24 protruding from the interface and a slot 25 at the interface, and the plug-in block 24 is adapted to the slot 25 in size. After the interfaces of the two arc-shaped discs 2 are jointed together, the plug-in units 23 at two interfaces are engaged with each other, so that the interfaces of the arc-shaped discs 2 may be effectively prevented from being dislocated. The interfaces of the arc-shaped discs 2 are perpendicular to the bolt axis, to facilitate the smooth jointing of the arc-shaped discs 2.

The kidney-shaped hole 211 of the ear plate 21 at the liftable section 6 penetrates the edge of the ear plate 21 to form a U-shaped groove, and the width of the opening 212 is smaller than the diameter of the attachment bolt. The end of the kidney-shaped hole of the ear plate 21 at the liftable section 6 are configured as a U-shaped groove in the form of the opening 212, which, on the one hand, reduces the material used for the parts of the ear plate 21 and the size of the quick-fitting structure as far as possible while ensuring that the contours of two ear plates 21 are consistent after being jointed, and on the other hand, helps to increase the inclination angle of the bolt and increase the expansion range of the clamp 1 without enlarging the length of the attachment bolt, thus facilitating the assembly of the clamp 1.

The implementation principle of the three-disc double-bolt quick coupler disclosed in Embodiment 1 is as follows. By the two adjacent arc-shaped discs 2, which are connected by the articulated connectors 3, there are two rotation axes, such that after the two rotary parts rotate relative to each other by a certain angle, the diameter of the arc-shaped disc 2 is enlarged greatly, thereby obtaining a relative larger adjustment range and a more flexible adjustment process compared with a traditional connection way with a single hinge. In the case where the number of the arc-shaped discs 2 of the clamp 1 is greater than or equal to three, taking the three arc-shaped discs 2 of the present embodiment as an example, after adjusting the angles of the two arc-shaped discs 2 using double hinges in the case where the bolt connectors 5 and the articulated connectors 3 are pre-mounted, referring to FIG. 3, the inner circle diameters of the two arc-shaped discs 2 are enlarged from A1 to be greater than or equal to the diameter D1 of the pipe, so that the clamp 1 may be smoothly sleeved on the pipe, then the height of the arc-shaped disc 2, namely the liftable section 6 may be adjusted correspondingly, by which the bolts connecting the liftable section 6 and the other two arc-shaped discs 2 are inclined in the kidney-shaped hole 211 and the U-shaped groove and the liftable section 6 is also located outside the contour of D1. By the multi-disc quick coupler in the present application, compared with a conventional quick coupler, on the one hand, the deformation is dispersed to all directions by provision of at least three arc-shaped discs 2, and the movement in the left and right directions is completed by the dislocation of the kidney-shaped hole or U-shaped groove relative to the attachment bolt, such that the remaining required movement distance in the length direction of the attachment bolt is much smaller, which effectively reduces the requirement for the bolt length; and on the other hand, by using an articulated connector 3 with two rotation axes as the rotational connection of adjacent arc-shaped discs 2, the adjustment of the relative position between the arc-shaped discs 2 is more flexible, such that the sleeve is easier to be sleeved on the pipe, there is no need to provide excessive allowance for the attachment bolt, the mounting is convenient and the efficiency is higher. By redesigning the angle of the arc-shaped disc 2 of the quick coupler and the position of the rotation axis of the articulated connector 3, the requirements for the bolt length are effectively reduced, the requirements for the screwing tool of the quick coupler are reduced, and additionally, the conventional hexagon socket wrench may be used for screwing, which is convenient for operation and reduces the production cost.

Taking the design of the three-disc double-bolt quick coupler disclosed in Embodiment 1 as an example, a design method for multi-disc quick coupler includes:

S1: determining a basic design size of the quick coupler. Referring to FIGS. 2 and 3, the actual diameter of the pipe to be connected with the quick coupler is D2, a margin is added in the calculation, so that an outer diameter of the pipe for calculation is set as D1=D2+0.5 mm, to ensure that the clamp 1 may be smoothly mounted, then the basic size of the quick coupler is so determined by the design standard and D1, that the inner diameter of the clamp 1 is A1, the outer diameter of the clamp 1 is A2, and the diameter of the slot at the inner sidewall of the clamp 1 is A3.

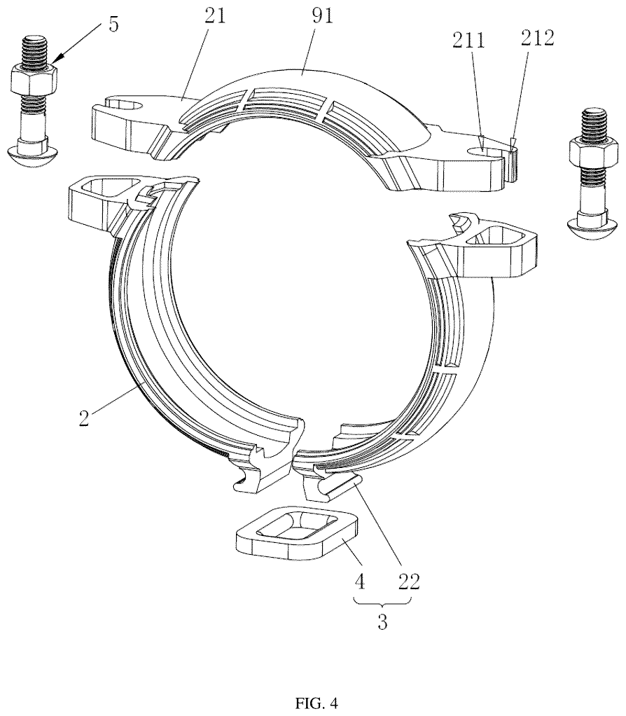

S2: Drawing up design variables. Referring to FIG. 5, the design variables include: a rotation radius R of the articulated connector 3; the position of the articulated connector 3, since the articulated connector 3 composed of the snap ring 4 and the latches 22 has two rotation axes, the distance between the rotation axes is 2T; taking the circle center of the clamp 1 in the closed state as a reference, the radian of the right arc-shaped disc 2 is θ1, and the radian of the right arc-shaped disc 2 is set as 120° according to experience for the convenience of subsequent calculation of coordinates, and the value range of θ1 is −90°≤θ1≤30°.

S3: Establishing a first Cartesian coordinate system. Referring to FIG. 3, the first Cartesian coordinate system is established with the central symmetry axis of the clamp 1 as the y-axis, and the x-axis of the first Cartesian coordinate system passes through the rotation axis of the articulated connector 3 at the end of the clamp 1 away from the bolt connector 5. The coordinates of point at the inner arc of the arc-shaped disc 2 in the first Cartesian coordinate system are (x1, y1), and the coordinates of the rotation axis of the articulated connector 3 in the first Cartesian coordinate system are (a1, b1).

Since the distance between the rotation axes is 2T, the coordinates of the two rotation axes of the articulated connector 3 are (T, 0), (−T, 0), respectively. The clamp 1 is symmetrical about the y-axis, and the right and left arc-shaped discs 2 are rotationally symmetrical, therefore, only the parameters of one arc-shaped disc 2 on one side need to be considered in the calculation, so the arc-shaped disc 2 on the right side of y-axis is calculated in the present embodiment.

When the clamp 1 is in a jointed state, the coordinates of the circle center of the clamp 1 are (0, O1), where

$$O 1 = \sqrt{{( \frac{A 2}{2} + R )}^{2} - {T}^{2}} .$$

The coordinates of point at the inner arc of the right arc-shaped disc 2 are (x1, y1), where

$$x 1 = \frac{A 1}{2} \times cos θ 1 , y 1 = \frac{A 1}{2} \times sin θ 1 + O 1 ,$$

where θ1 is the radian of the clamp 1 corresponding to a specific point at the inner arc of the right arc-shaped disc 2. Considering the limit state when the rotation angle of the arc-shaped disc 2 is minimum, the arc-shaped disc 2 is in contact with the outer contour of the pipe only with the endpoints of the inner arc thereof, so only the coordinates of the two endpoints of the inner arc of the arc-shaped disc 2 need to be calculated in the calculation, i.e., θ1=−90° and θ1=30°.

S4: Establishing a first polar coordinate system. The origin of the first Cartesian coordinate system is moved to the right rotation axis of the articulated connector 3 to form a first hinge point Cartesian coordinate system so as to obtain a first conversion function between the coordinates of point in the first hinge point Cartesian coordinate system and that in the first Cartesian coordinate system, by which the coordinates of point at the clamp 1 in the first hinge point Cartesian coordinate system are (x2, y2), and the first conversion function is x2=x1−a1, y2=y1−b1; i.e., x2=x1−T and y2=y1.

Then, establishing the first polar coordinate system with the right rotation axis of the articulated connector 3 as the origin to facilitate the rotation transformation, and the second conversion function between the coordinates of point in the first polar coordinate system and that in the first hinge point Cartesian coordinate system may be calculated, where the coordinates of point at the clamp 1 in the first polar coordinate system are (ρ, θₚₒₗₑ), and the second conversion function is

$$ρ = \sqrt{x {2}^{2} + y {2}^{2}} , {θ}_{p o l e} = atan \frac{y 2}{x 2} .$$

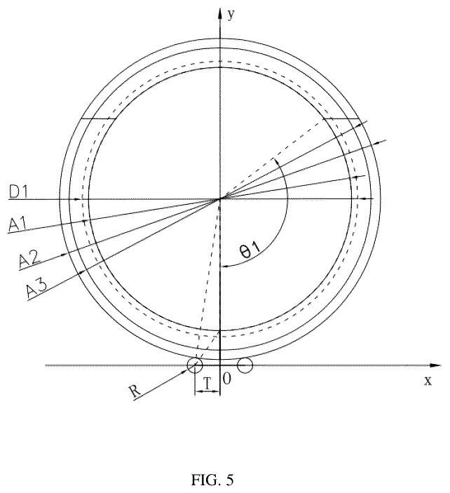

S5: Calculating the coordinates after rotation. The first conversion function and the second conversion function are input into a mathematical calculation software, and the polar coordinates of point at the inner arc of the arc-shaped disc 2 after rotation are input into the mathematical calculation software, so that the coordinates of point in the first Cartesian coordinate system after rotation may be inversely calculated. Referring to FIG. 6, the right arc-shaped disc 2 is rotated clockwise by Δθ about the right rotation axis, and the polar coordinates of point at the inner arc of the arc-shaped disc 2 in the polar coordinate system after rotation are (ρ, θpole−Δθ), the coordinates of point at the inner arc of the right arc-shaped disc 2 in the first hinge point Cartesian coordinate system after rotation are (x3, y3), where x3=ρ×cos (θpole−Δθ), y3=ρ×sin (θpole−Δθ), and the coordinates of point at the inner arc of the right arc-shaped disc 2 in the first Cartesian coordinate system after rotation are (x4, y4), where x4=x3+a1, y4=y3+b1; i.e., x4=x3+T, and y4=y3.

S6: Calculating the distance between the point at the arc-shaped disc 2 and the circle center of the pipe contour to ensure that the right arc-shaped disc 2 is outside the pipe contour, and calculating the minimum value of Δθ.

Since the arc-shaped disc 2 is a circular arc, in the limit state where Δθ has the minimum value, the endpoints of the two ends of the inner arc of the arc-shaped disc 2 just fall on the pipe contour. In addition, since the clamp 1 is of an axisymmetric structure, the rotation angles of the left and right arc-shaped discs 2 in the limit state where Δθ has the minimum value are also symmetrical, and the circle center of the pipe contour is always located on the y-axis of the first Cartesian coordinate system.

S61: Calculating the position of the circle center of the pipe contour (xcircle, ycircle), where xcircle=0. The position of the circle center of the pipe contour is calculated based on the fact that the initial point of the inner arc of the right arc-shaped disc 2 (the end point of the inner arc close to the rotation axis, θ1=−90°) always abuts against the edge of the pipe contour, where the coordinates of the end point of the inner arc are (x41, y41), the difference between the ycircle and y41 is

$$\sqrt{{( \frac{D 1}{2} )}^{2} - {x}_{41}^{2}} , so ycircle = y 41 + \sqrt{{( \frac{D 1}{2} )}^{2} - {x}_{41}^{2}} .$$

S62: Calculating the distance between the terminal point of the inner arc of the right arc-shaped disc 2 (the end point of the inner arc away from the rotation axis) and the circle center of the pipe contour (0, O2) to determine whether the terminal point of the inner arc of the right arc-shaped disc 2 is located out of the pipe contour. The position of the circle center of the pipe contour is calculated with the initial point of the inner arc of the right arc-shaped disc 2, where θ corresponding to the initial point is −90°, and the position of the circle center of the pipe contour is (0, O2),

$$O 2 = \sqrt{{( \frac{D 1}{2} )}^{2} - x {4}^{2}} + y 3 ;$$

the distance between the terminal point of the inner arc of the right arc-shaped disc 2 and the circle center of the pipe contour is L1={square root over ((x4²−(y3−O2)²)}, when L1 is greater than or equal to D1/2, the terminal point is located out of the pipe contour and does not interfere with the insertion of the pipe.

S63: Calculating the minimum value of Δθ. When L1=D1/2, the terminal point of the arc-shaped disc 2 just falls on the pipe contour of diameter D1. When the rotation angle of the arc-shaped disc 2 is reduced during the design process, it helps to reduce the distance between the right or left arc-shaped disc 2 and the liftable section 6 after the clamp 1 opens, which helps to reduce the requirements for the length of the attachment bolt. When the arc-shaped disc 2 rotates around the rotation axis, the vertical distance between the terminal end of the arc-shaped discs 2 (away from the hinge and close to the liftable section 6) and the liftable section 6 increases monotonically, the smaller the rotation angle Δθ, the smaller the vertical distance between the terminal end of the arc-shaped disc 2 and the liftable section 6 is, i.e., the smaller the required length of the attachment bolt is.

The minimum value of the rotation angle Δθ of the right arc-shaped disc 2 may be obtained by a computer under using a dichotomy method, and the specific method is: firstly, setting a rotation boundary of the rotation angle Δθ of the arc-shaped disc 2 with the minimum Δθ being 0° while the maximum Δθ being 90°, so carrying out the first calculation with Δθ=(0+90)/2, i.e., Δθ=45°, if the calculation result indicates that the terminal point is out of the pipe contour (both L1 are greater than D1/2), it is indicated that the opening angle is too large, then carrying out a calculation again with Δθ=(0+45)/2, i.e., Δθ=22.5°, if the calculation result indicates that the terminal point is inside the maximum pipe, it is indicated that the opening angle is too small, then carrying out a calculation with (22.5+45)/2, until L1 of the endpoints of the two ends of the inner arc of the arc-shaped disc 2 is equal to D1/2.

The displacement of the liftable section 6 of the arc-shaped disc 2 is calculated. The radian of the liftable section 6 is θ3=360−2×θ1. Since the right and left arc-shaped discs 2 rotate symmetrically, the pipe contour rises along the y-axis of the first Cartesian coordinate system. If it is desired that the liftable section 6 does not interfere with the pipe contour, the minimum displacement is so, that the endpoints of the two ends of the inner arc of the liftable section 6 fall on the pipe contour and rise along the y-axis. The coordinate of the circle center of the liftable section 6 after lifting is (0, O3),

$$O 3 = O 2 + \sqrt{{( \frac{A 1}{2} \times cos ( \frac{θ 3}{2} ) )}^{2} - {( \frac{A 1}{2} )}^{2} + {( \frac{D 1}{2} )}^{2}} - \frac{A 1}{2} \times cos ( \frac{θ 3}{2} ) = O 2 + \sqrt{{( \frac{A 1}{2} \times cos ( 180 - θ 1 ) )}^{2} - {( \frac{A 1}{2} )}^{2} + {( \frac{D 1}{2} )}^{2}} - \frac{A 1}{2} \times cos ( 180 - θ1 ) .$$

The lifting height of the liftable section 6 is H=O3−O1, the shortest adjustment length required for the attachment bolt may be calculated according to H, and then the shortest length of the attachment bolt may be calculated combined with the thickness of the lug. The adjustment range required for the kidney-shaped hole 211 may be calculated by separately calculating the lateral offset distance of the right and left arc-shaped discs 2 without lateral moving the liftable section 6.

S7: Inputting the above-mentioned calculation formula of L1 into the mathematical function software, carrying out a loop computation by changing a certain design variable individually, so as to derive a relation curve of the influence of each design variable on the minimum rotation angle Δθ, performing a design according to the change trend of the relation curve and the extent of influence, and selecting a parameter capable of reducing the bolt length.

The design variables include the rotation radius R of the rotary part, the distance 2T between the two rotation axes of the articulated connector 3, the radian θ1 of the right arc-shaped disc 2, the deviation c between the radian of the inner arc and the radian of the outer arc of arc-shaped disc 2, namely the liftable section 6.

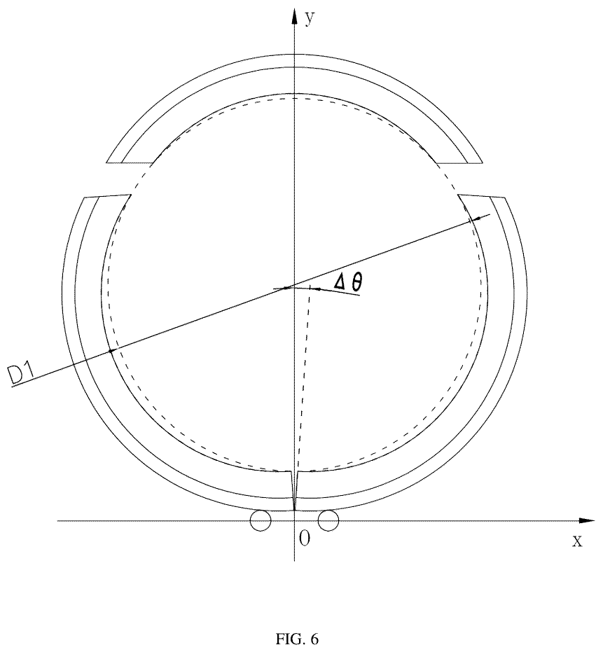

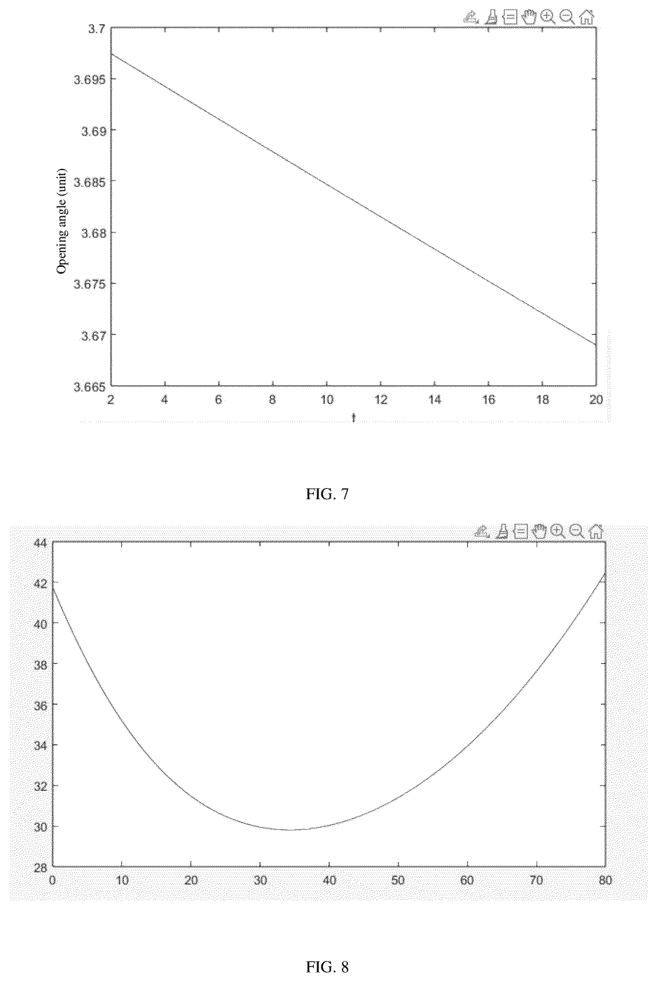

A curve of Δθ with T may be obtained by cycling T in a computer program. Referring to FIG. 7, the vertical axis represents the size of the opening angle, i.e., Δθ, and the horizontal axis is T. With the increase of T, the change of the opening angle is small, but the snap ring 4 shall be greatly opened for increasing T, it is not a good measure to reduce the opening angle for increasing T. It also reflects that it is more helpful for reducing the length of the attachment bolt with the connection with dual rotation axes compared to a single articulated connection. The same effect may be obtained when cycling R. The design of variables R and T are both for increasing the distance between the rotation center and the rotation axis, but since the increased amount is very small for the clamp 1 itself, the effect is very small.

Then the relationship between the radian of the inner arc of each arc-shaped disc 2 of the clamp 1 and Δθ is in turn. Since the right and left arc-shaped discs 2 are symmetrical, so the determination of the angle of one disc means the determination of the angles of all three discs, therefore, only the relation curve between Δθ and θ1 needs to be analyzed. Referring to FIG. 8, the x-axis represents the angle θ1 of the right disc. Since it is calculated from −90°, the 30° shown in FIG. 7 means that the radian of the right arc-shaped disc 2 is 120°. Y-axis represents Δθ. It may be seen that the extreme value occurs around 120°, and the difference between 120° and the extreme value point is not great. Therefore, in Embodiment 1, the radian of the inner arc of each arc-shaped disc 2 is 120°.

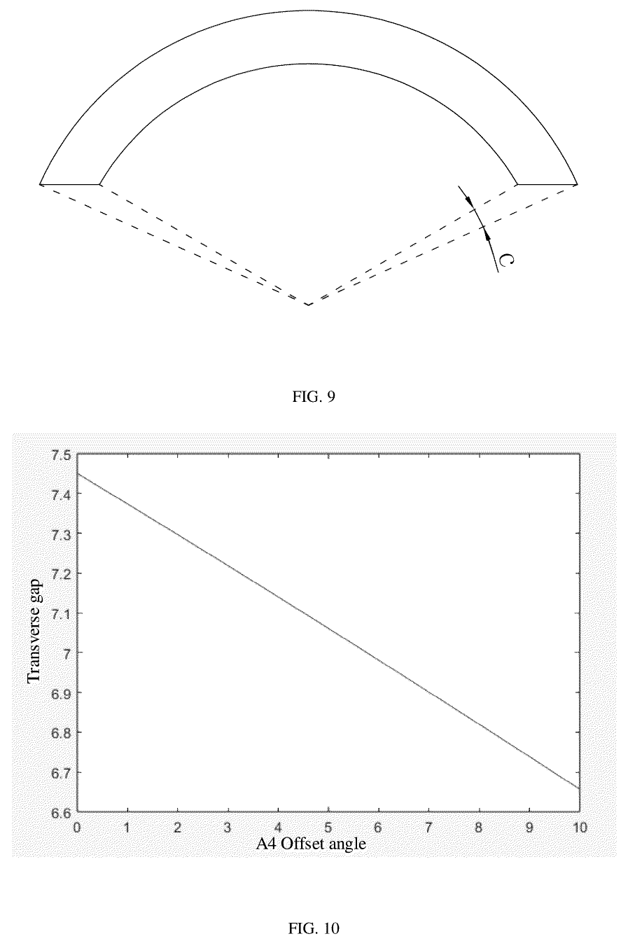

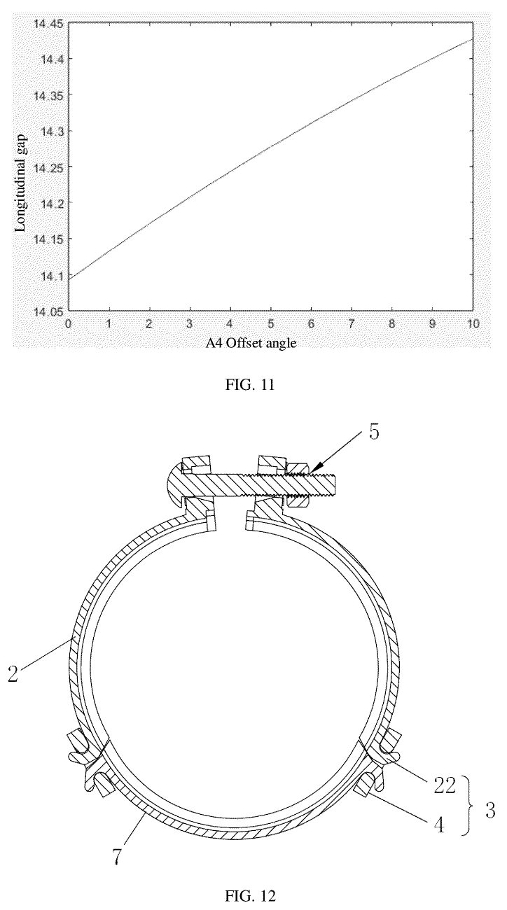

After determining the radian of the inner arc of arc-shaped disc 2, the outer arc (the arc with diameter A2) is offset based on the inner arc. Referring to FIG. 9, the outer arc is offset by c° with respect to the inner arc. The transverse distance refers to the distance in the x-axis direction between the peripheral end point of the liftable section 6 and the peripheral end point of the right arc-shaped disc 2 at the minimum opening angle, and the longitudinal distance refers to the distance in the y-axis direction between the peripheral end point of the liftable section 6 and the peripheral end point of the right arc-shaped disc 2 at the minimum opening angle. FIG. 10 is a deviation angle c as a function of the transverse distance. FIG. 11 shows a deviation angle c as a function of the longitudinal distance. It may be seen that as the deviation angle increases, the lateral distance decreases from 7.45 to 6.65, it changes about 0.8, while the longitudinal distance changes by only about 0.3 and is very small. However, the longitudinal distance is directly related to the length of the attachment bolt, and the transverse distance mainly influences the adjustment length of the kidney-shaped hole 211 and the U-shaped hole, i.e., influences the length of the ear plate 21 required to be designed. The deviation angle c has less influence on the length of the attachment bolt in the design.

In summary, it is possible to calculate and select the better rotation radius R of the rotary part, the distance 2T between the two rotation axes of the articulated connector 3, the radian θ1 of the right arc-shaped disc 2 and the deviation c between the radian of the inner arc and that of the outer arc of the liftable section 6, to obtain a shorter design length of the attachment bolt. This design method is helpful to shorten the length of the attachment bolt of the quick coupler, such that it is convenient to use the common wrench to screw the nut, thereby reducing the production cost under the premise of ensuring the experience of the quick coupler.

### Embodiment 2

Referring to FIG. 12, Embodiment 2 discloses a three-disc single-bolt quick coupler, which differs from Embodiment 1 in that two of the three interfaces of the circumferential contour of the clamp 1 are coupled by means of articulated connectors 3 and the other one is coupled by means of a bolt connector 5. The installation efficiency of the quick coupler may be improved by reducing the number of the bolt connectors 5, so as to shorten the duration required to screw the nut. The mounting holes at two ear plates 21 for the bolt connectors 5 are closed kidney-shaped holes 211.

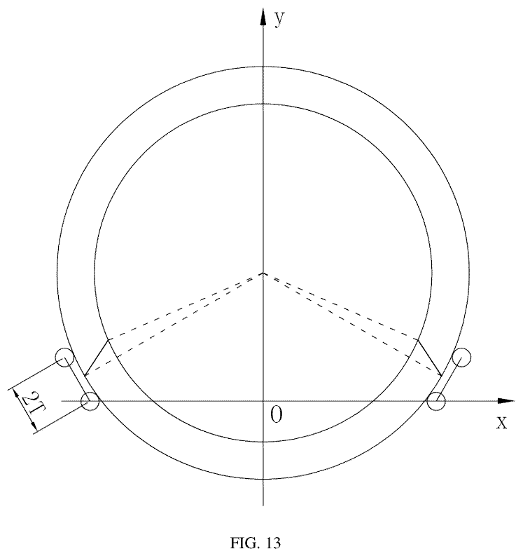

Referring to FIGS. 12 and 13, taking the arc-shaped disc 2 between the two articulated connectors 3 as the bottom disc 7, it is default that the bottom disc 7 is stationary and the arc-shaped discs 2 on the left and right side of the bottom disc 7 rotate when performing the design calculation. The overall structure of the clamp 1 is symmetrical with respect to the middle axis of the bottom disc 7, and the arc-shaped discs 2 on the left and right side of the bottom disc 7 rotate symmetrically during the rotation for expansion.

### Embodiment 3

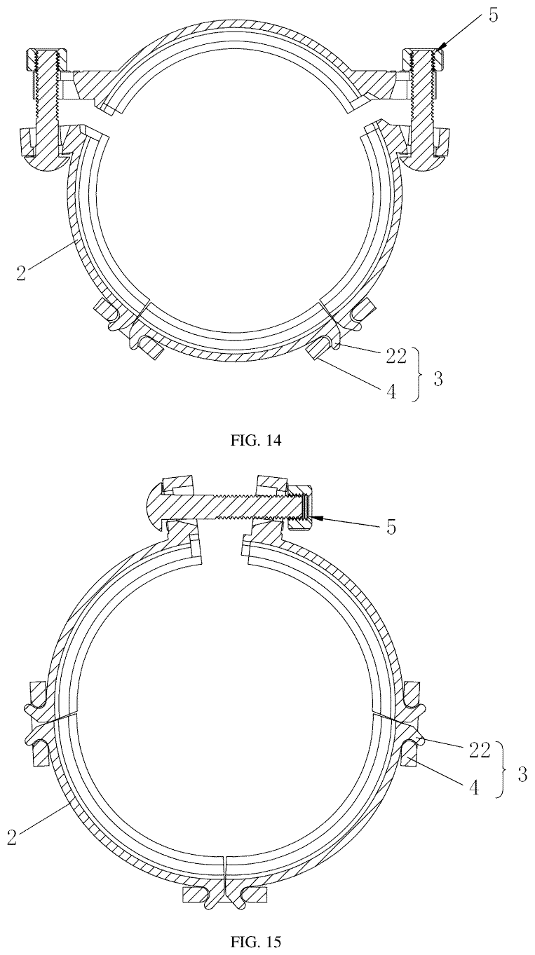

Referring to FIG. 14, the present embodiment discloses a four-disc quick coupler with two bolt connectors 5 and two latch articulated connectors 3, which differs from Embodiment 1 in that the clamp 1 is made up of four arc-shaped arc discs 2. Two pairs of four pairs of interfaces in the circumferential direction of the clamp 1 are connected with each other by means of the articulated connectors 3, the articulate connector includes a latch 22 and a rotary part, while the other two pairs of interfaces are connected with each other by means of the bolt connectors 5 in cooperation with ear plates 21.

### Embodiment 4

Referring to FIG. 15, the present embodiment discloses a four-disc quick coupler with three latch articulated connectors 3 and one bolt connector 5, which differs from Embodiment 1 in that the clamp 1 is made up of four arc-shaped arc discs 2. Three pairs of four pairs of interfaces in the circumferential direction of the clamp 1 are connected with each other by means of the articulated connectors 3, the articulated connector includes a latch 22 and a rotary part, while the other pair of interfaces are connected with each other by means of the bolt connector 5 in cooperation with ear plates 21.

### Embodiment 5

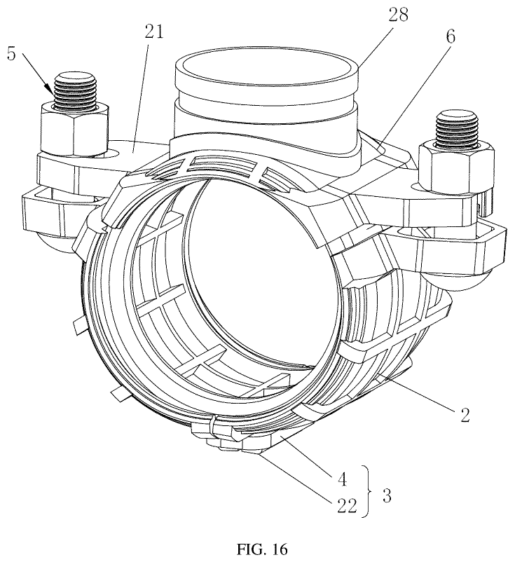

Referring to FIG. 16, the present embodiment discloses a tee three-disc quick coupler with one latch articulated connector 3 and two bolt connectors 5, which is suitable for a three-way pipeline. The present embodiment differs from Embodiment 1 in that the liftable section 6 of the clamp 1 is provided with a hollow cylindrical three-way junction 29, where the axial length of the clamp 1 is relatively long, so as to leave enough room for the three-way junction 29.

### Embodiment 6

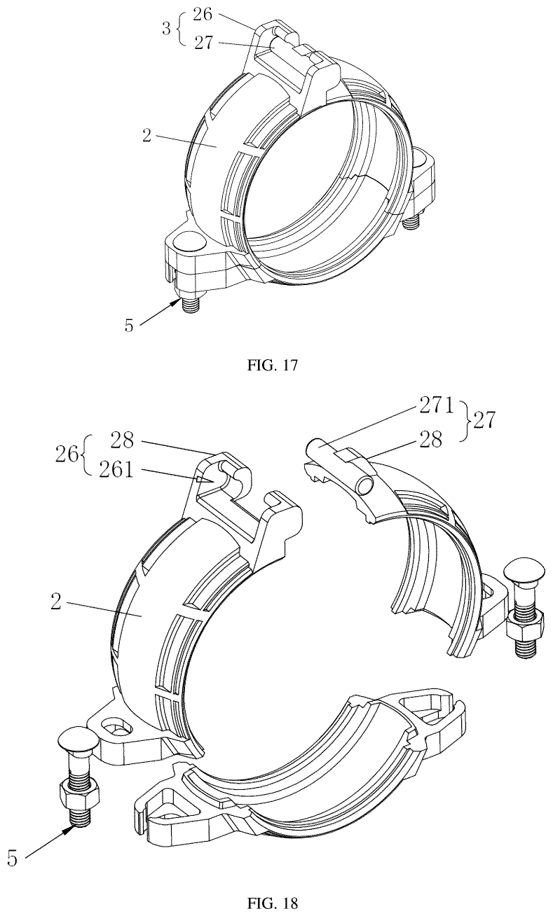

Referring to FIGS. 17 and 18, the present embodiment discloses a three-disc quick coupler with a male and female hinge and two bolt connectors 5, which differs from Embodiment 1 in that the articulated connector 3 includes a pin assembly 27 and a slot assembly 26, and the pin assembly 27 and the slot assembly 26 are respectively fixed at the ends of adjacent arc-shaped discs 2. The slot assembly 26 includes two connecting arms 28 with hinge slots 261, the hinge slots 261 are defined on opposite sidewalls of the two connecting arms 28, and the hinge slots 261 are offset to a side of the connecting arms 28 away from the adjacent arc-shaped disc 2 and form pin mounting openings on the side of the connecting arms 28 away from the adjacent arc-shaped disc 2. The pin assembly 27 is a connecting arm 28 with a hinge pin 271, the connecting arm 28 of the pin assembly 27 extends between two connecting arms 28 of the slot assembly 26, two ends of the connecting arm 28 of the pin assembly 27 are respectively provided with a hinge pin 271 corresponding to the hinge slot 261, and the hinge pin 271 may be inserted into the hinge slot 261 from the pin mounting opening.

### Embodiment 7

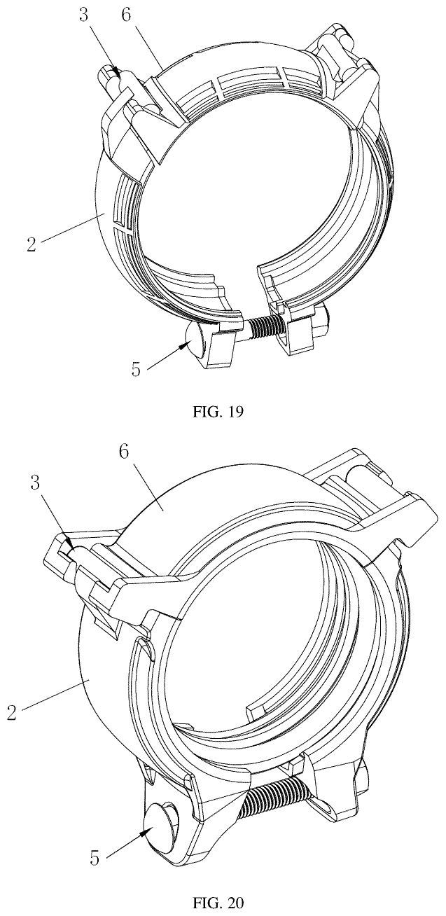

Referring to FIG. 19, the present embodiment discloses a three-disc quick coupler with two male and female hinges and one bolt connectors, which differs from Embodiment 2 in that the articulated connector 3 is designed as the male and female hinge as shown in FIG. 18.

FIG. 20 shows an alternative quick coupler design of the present embodiment, where the outer circumferential surface of the clamp is changed from arcuate to planar.

### Embodiment 8

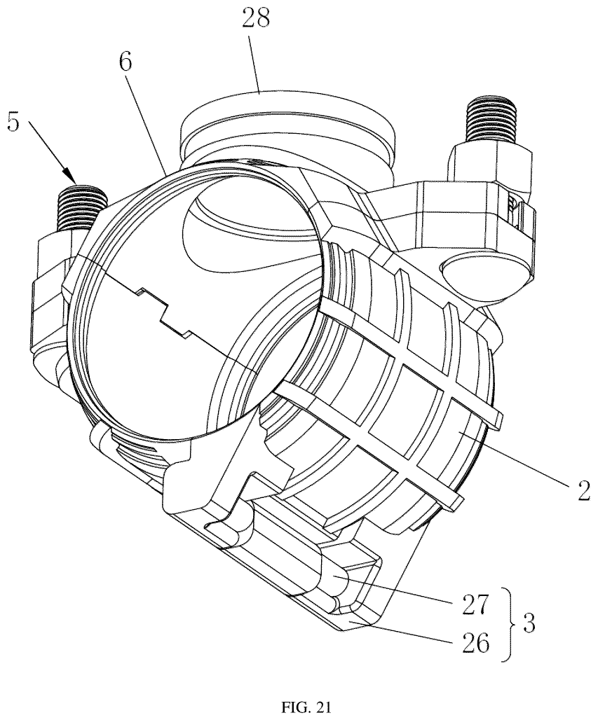

Referring to FIG. 21, the present embodiment discloses a tee three-disc quick coupler with one male and female hinge and two bolt connectors 5, which differs from Embodiment 5 in that the articulated connector 3 is designed as the male and female hinge as shown in FIG. 23.

### Embodiment 9

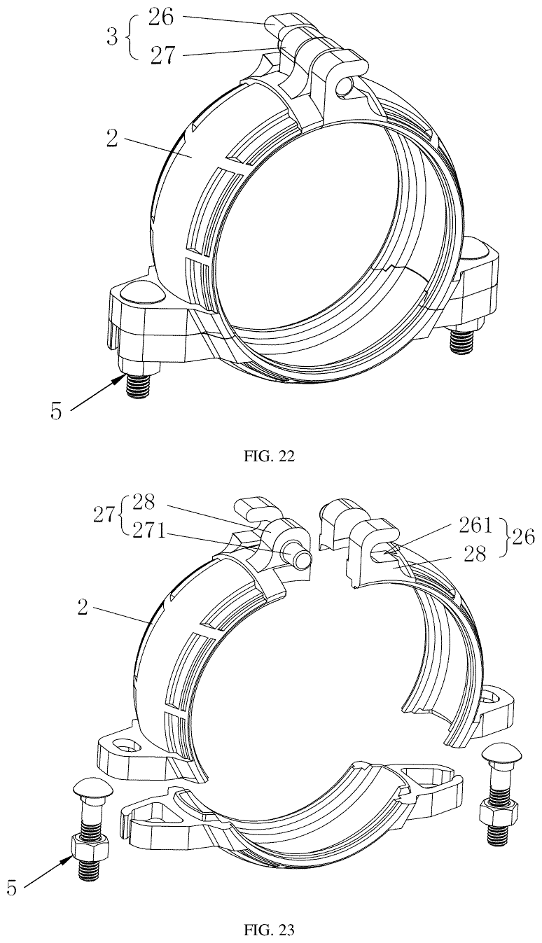

Referring to FIGS. 22 and 23, the present embodiment discloses a three-disc quick coupler with one symmetrical hinge and two bolt connectors 5, which differs from Embodiment 1 in that the articulated connector 3 includes a rotary rod with a hinge slot 261 and a rotary rod with a hinge pin 271 at ends of adjacent arc-shaped discs 2, where the ends of the arc-shaped discs 2 are respectively provided with a rotary rod with a hinge slot 261 and a rotary rod with a hinge pin 271, the hinge slot 261 is open towards the adjacent arc-shaped disc 2, and the hinge pin 271 is rotatably inserted in the hinge slot 261.

### Embodiment 10

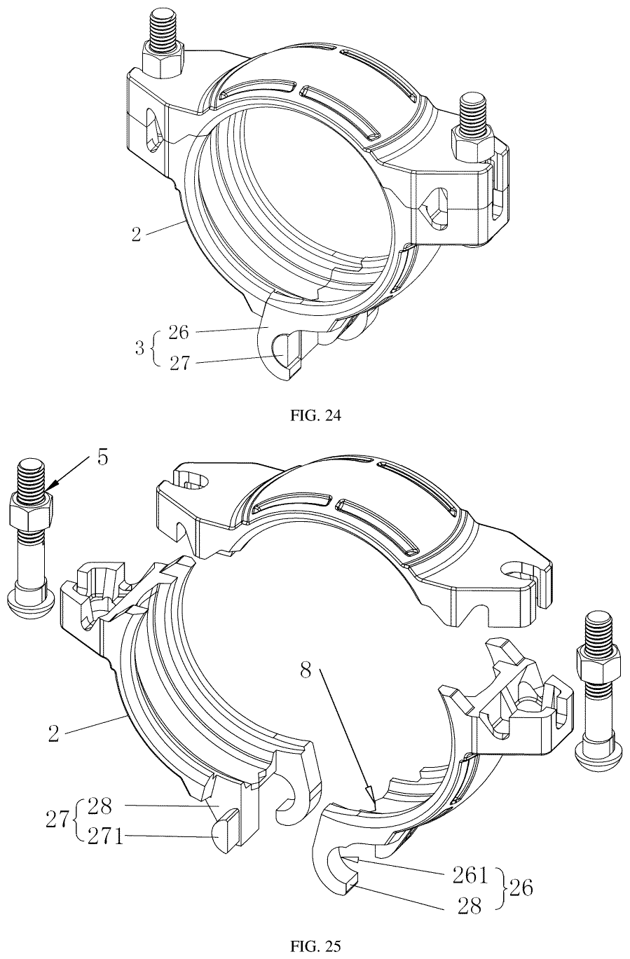

Referring to FIGS. 24 and 25, the present embodiment also discloses a three-disc quick coupler with one symmetrical hinge and two bolt connectors 5, which differs from Embodiment 9 in that the hinge pin 271 is designed as a semi-cylinder, and the rotary rod where the hinge pin 271 is provided is correspondingly shortened, the end faces of the two arc-shaped discs 2, to which the symmetrical hinge is connected, are provided with staggered teeth 8 for axial limitation, and in the closed condition of the quick coupler, the cross section of the semi-cylindrical hinge pin 271 is located on the side away from the corresponding hinge slot 261.

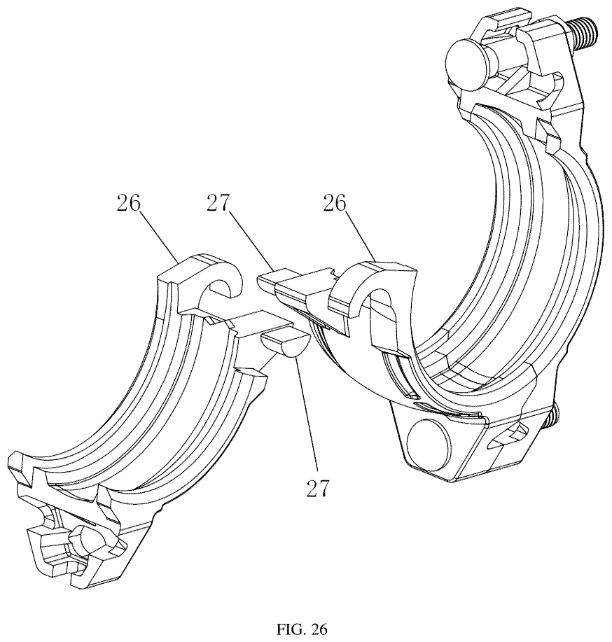

Referring to FIG. 26, in comparison with Embodiment 9, the present embodiment is more convenient in assembling a symmetrical hinge, in which the two parts of the symmetrical hinge are laterally inserted and then relatively rotated, and the connection is completed.

### Embodiment 11

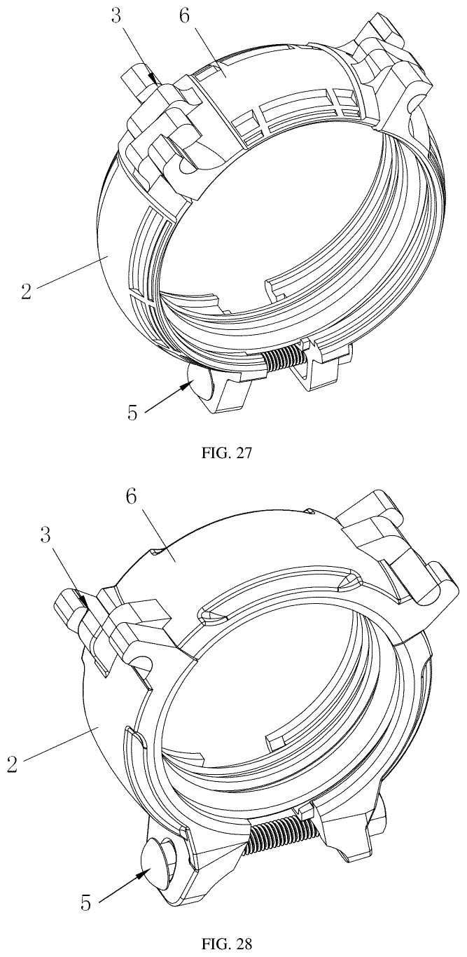

Referring to FIG. 27, the present embodiment discloses a three-disc quick coupler with two symmetrical hinges and one bolt connector 5, which differs from Embodiment 7 in that the articulated connector 3 is designed as the symmetrical hinge as shown in FIG. 25.

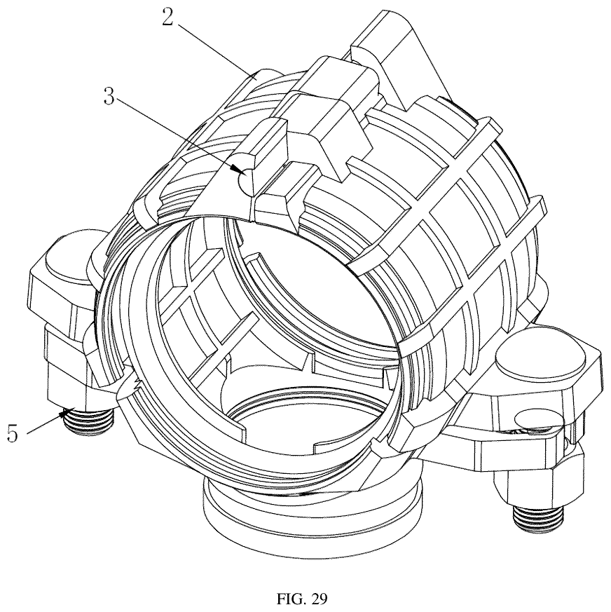

FIG. 28 is another quick coupler design of the present embodiment with the outer circumferential surface of the clamp changing from arcuate to flat.

### Embodiment 12

Referring to FIG. 29, the present embodiment discloses a tee three-disc quick coupler with one symmetrical hinge and two bolt connectors 5, which differs from Embodiment 8 in that the articulated connector 3 is designed as the symmetrical hinge as shown in FIG. 25.

The above are the preferred embodiments of the present application, and the protection scope of the present application is not limited thereby, therefore, equivalent changes made according to the structure, shape and principle of the present application shall be covered by the protection scope of the present application.

### LIST OF REFERENCE NUMERALS

1 clamp
2 arc-shaped disc
21 ear plate
211 kidney-shaped hole
212 opening
22 latch
23 plug part
24 plug-in block
25 slot
26 slot assembly
261 hinge slot
27 pin assembly
271 hinge pin
28 connecting arm
29 three-way junction
3 articulated connector
4 snap ring
5 bolt connector
6 liftable section
7 bottom disc
8 staggered teeth

What is claimed is:

1. A design method for a multi-disc quick coupler, comprising a clamp, a bolt connector and an articulated connector, the clamp is configured as an annular coupler formed by jointing at least three arc-shaped discs, the clamp is of an axisymmetric structure as a whole, and the articulated connector or the bolt connector is mounted between adjacent arc-shaped discs of the at least three arc-shaped discs to connect the adjacent arc-shaped discs,
wherein the design method for a multi-disc quick coupler comprises:
S1: determining a basic design size of the multi-disc quick coupler, the basic design size comprises a first diameter (A2) of an outer arc of the clamp, a second diameter (A1) of an inner arc of the clamp, and a diameter (D1) of an outer arc of a pipe to be connected,
S2: formulating design variables comprising a radian of each of the at least three arc-shaped discs of the clamp and a position of each of rotation axes of the articulated connector, wherein a specific angle, size or position parameter is formulated for each of the design variables,
S3: establishing a first Cartesian coordinate system, wherein the first Cartesian coordinate system is established with a central symmetry axis of the clamp as a y-axis, an x-axis of the first Cartesian coordinate system passes through a first rotation axis of the rotation axes of the articulated connector at a side of the clamp away from the bolt connector, and coordinates of the first rotation axis of the rotation axes of the articulated connector and coordinates of endpoints of each of the at least three arc-shaped discs are calculated according to the basic design size and the design variables,
S4: establishing a first polar coordinate system, wherein an origin of the first Cartesian coordinate system is moved to the first rotation axis of the rotation axes of the articulated connector to form a first hinge point Cartesian coordinate system, so as to obtain first conversion functions between coordinates of point in the first hinge point Cartesian coordinate system and coordinates of point in the first Cartesian coordinate system, then the first polar coordinate system is established with the first rotation axis of the rotation axes of the articulated connector as an origin of the first polar coordinate system, and second conversion functions between coordinates of point in the first polar coordinate system and the coordinates of point in the first hinge point Cartesian coordinate system is calculated,
S5: calculating coordinates after rotation, wherein the first conversion functions and the second conversion functions are input into mathematical calculation software, and polar coordinates of point after rotation are input into the mathematical calculation software, so that coordinates of point in the first Cartesian coordinate system after rotation are inversely calculated,
S6: calculating a minimum rotation angle, wherein the minimum rotation angle is a rotation angle of the articulated connector, by which a diameter of an incircle of an inner arc of each of the at least three arc-shaped discs at the endpoints is equal to the diameter (D1) of the outer arc of the pipe to be connected, and
S7: verifying an influence of the design variables and determining the design variables, wherein a value of a single one of the design variables is changed, the minimum rotation angle is calculated through the S6, function relationship curves of the minimum rotation angle with each of the design variables are obtained through loop calculation of the mathematical calculation software, and a design variable value for reducing the minimum rotation angle is selected.

2. The design method for a multi-disc quick coupler according to claim 1, wherein in the S3 of establishing the first Cartesian coordinate system, the coordinates of point of each of the at least three arc-shaped discs in the first Cartesian coordinate system are (x1, y1), and the coordinates of the first rotation axis of the rotation axes of the articulated connector in the first Cartesian coordinate system are (a1, b1);
in the S4 of establishing the first polar coordinate system, the coordinates of point at the clamp in the first hinge point Cartesian coordinate system are (x2, y2), the first conversion functions are x2=x1−a1, y2=y1−b1, the coordinates of point at the clamp in the first polar coordinate are (ρ, θₚₒₗₑ), and the second conversion function is
$$ρ = \sqrt{x {2}^{2} + y {2}^{2}} , {θ}_{p o l e} = atan \frac{y 2}{x 2} ,$$
in the S5 of calculating the coordinates after rotation, the rotation angle is set to be Δθ, the polar coordinates of point at the clamp after rotation are (ρ, θpole−Δθ), the coordinates of point at the clamp in the first hinge point Cartesian coordinate system after rotation are (x3, y3), x3=ρ×cos(θpole−Δθ), y3=ρ×sin(θpole−Δθ), the coordinates of point at the clamp in the first Cartesian coordinate system after rotation are (x4, y4), x4=x3+a1, y4=y3+b1, and
the S6 of calculating the minimum rotation angle comprises: S61: calculating coordinates (circle x, circle y) of a circle center of a contour of the pipe to be connected in the first Cartesian coordinate system, wherein circle x=0, determining a position of the circle center of the contour of the pipe to be connected by taking two respective endpoints of an uppermost arc-shaped disc and a lowermost arc-shaped disc of the at least three arc-shaped discs in a direction of the y-axis as locating points, wherein coordinates of two respective endpoints of the inner arcs of the uppermost arc-shaped disc and the lowermost arc-shaped disc of the at least three arc-shaped discs in the direction of the y-axis are respectively calculated through S5 as (x41, y41) and (−x41, y41), a difference between the circle y and y41 is
$$\sqrt{{( \frac{D 1}{2} )}^{2} - {x}_{41}^{2}} ,$$
and circle
$$y = y 41 + \sqrt{{( \frac{D 1}{2} )}^{2} - {x}_{41}^{2}} ;$$
S62: calculating a distance from remaining endpoints of the inner arcs of the uppermost arc-shaped disc and the lowermost arc-shaped disc of the at least three arc-shaped discs in the direction of the y-axis to the circle center of the contour of the pipe to be connected, L1=\sqrt{y4²+(y4−circle y)²}; and S63: calculating a minimum value of the Δθ, and setting the minimum value Δθ3 when
$$L 1 \geq \frac{D 1}{2} .$$

3. The design method for a multi-disc quick coupler according to claim 2, wherein when the x-axis of the first Cartesian coordinate system passes through two rotation centers, the two rotation centers on the x-axis are stationary, arc-shaped discs of the at least three arc-shaped discs on a left and on a right of a connection line between the two rotation centers, namely a left arc-shaped disc and a right arc-shaped disc, rotate, a distance between the two rotation centers is 2T, and coordinates of two of the rotation axes of the articulated connector are (T, 0) and (−T, 0), respectively,
coordinates of a circle center of the clamp are (0, O1),
$$O 1 = \sqrt{{( \frac{A 2}{2} + R )}^{2} - {T}^{2}}$$
in a jointed state of the clamp,
the coordinates of point at the inner arc of each of the at least three arc-shaped discs are (x1, y1),
$$x 1 = \frac{A 1}{2} \times cos θ 1 , y 1 = \frac{A 1}{2} \times sin θ 1 + O 1 ,$$
θ1 is a radian of the clamp corresponding to a specific point on the inner arc of the right arc-shaped disc,
the coordinates of point on the inner arc of the right arc-shaped disc in the first hinge point Cartesian coordinate system with a right rotation axis of the rotation axes of the articulated connector as the origin are (x2, y2), x2=x1−T, y2=y1,
the coordinates of point at the inner arc of the right arc-shaped disc in the first polar coordinate system with the right rotation axis of the rotation axes of the articulated connector as the origin are (ρ, θpole),
$$ρ = \sqrt{x {2}^{2} + y {2}^{2}} , θ pole = atan \frac{y 2}{x 2} ,$$
after the right arc-shaped disc rotates clockwise around the right rotation axis of the rotation axes of the articulated connector by Δθ, the polar coordinates of point at the inner arc of the right arc-shaped disc in the first polar coordinate system after rotation are (ρ, θpole−Δθ),
the coordinates of point at the inner arc of the right arc-shaped disc in the first hinge point Cartesian coordinate system are (x3, y3), x3=ρ×cos(θpole−Δθ), y3=ρ×sin(θpole−Δθ),
the coordinates of point at the inner arc of the right arc-shaped disc in the first Cartesian coordinate system after rotation are (x4, y4), x4=x3+T, y4=y3,
the position of the circle center of the contour of the pipe to be connected is calculated with an initial point of the inner arc of the right arc-shaped disc, θ corresponding to the initial point is −90°, the position of the circle center of the contour of the pipe to be connected is (0, O2),
$$O 2 = \sqrt{{( \frac{D 1}{2} )}^{2} - x {4}^{2}} + y 3 ,$$
a distance between a terminal point of the right arc-shaped disc and the circle center of the contour of the pipe to be connected is L1={square root over ((x4²−(y3−O2)²)},
the value for Δθ satisfies
$$L 1 \geq \frac{D 1}{2} ,$$
and the minimum rotation angle Δθ of the right arc-shaped disc is obtained by using a dichotomy method.

4. The design method for a multi-disc quick coupler according to claim 2, wherein after calculating the minimum rotation angle and the radian of a first one of a right arc-shaped disc and a left arc-shaped disc of the clamp, the minimum rotation angle and the radian of a second one of the right arc-shaped disc and the left arc-shaped disc of the clamp are obtained based on the axisymmetric structure of the clamp, and finally a radian of a third one of the at least three arc-shaped discs is calculated.

5. The design method for a multi-disc quick coupler according to claim 1, wherein when more than one rotation axes of the articulated connector of one of the at least three arc-shaped discs of the clamp are provided, a second Cartesian coordinate system and a second hinge point Cartesian coordinate system are established based on each of the rotation axes, and the S3 and the S4 are repeated, wherein a rotation axis more close to the origin of the first Cartesian coordinate system in the S3 is set as the first rotation axis, and following steps are carried out:
S3-1: establishing the second Cartesian coordinate system, wherein the first rotation axis is taken as a hinge origin of the second Cartesian coordinate system, a y-axis of the second Cartesian coordinate system is parallel to the y-axis of the first Cartesian coordinate system, an x-axis of the second Cartesian coordinate system passes through a second rotation axis on a side of the first rotation axis away from the hinge origin of the second Cartesian coordinate system, and calculating coordinates (a2, b2) of a position of the second rotation axis in the second Cartesian coordinate system and coordinates (x12, y12) of a position of point at the inner arc of each of the at least three arc-shaped discs according to the basic design size of the multi-disc quick coupler and the design variables; and
S4-1: establishing a second polar coordinate system, wherein the hinge origin of the second Cartesian coordinate system is moved to the second rotation axis to form the second hinge point Cartesian coordinate system, coordinates of point at the clamp in the second hinge point Cartesian coordinate system are (x22, y22), third conversion functions x22=x12−a2, y22=y12−b2 of the coordinates of point in the second hinge point Cartesian coordinate system and the coordinates of point of the second Cartesian coordinate system are obtained, the second polar coordinate system is established with a respective one of the rotation axes of the articulated connector as an origin, wherein coordinates of point at the clamp in the second polar coordinate system are (ρ2, θₚₒₗₑ₂), and fourth conversion functions
$$ρ 2 = \sqrt{x {22}^{2} + y {22}^{2}} , {θ}_{p ole 2} = atan \frac{y 22}{x 22}$$
between the coordinates of point in the second polar coordinate system and the coordinates of point in the second hinge point Cartesian coordinate system are calculated.

6. The design method for a multi-disc quick coupler according to claim 5, wherein one of two ends of each of the at least three arc-shaped discs is provided with an ear plate for the bolt connector, a bolt mounting hole at the ear plate for the bolt connector is a kidney-shaped hole, a length direction of a kidney of the kidney-shaped hole is perpendicular to the central symmetry axis of the clamp, in the S6 of calculating the minimum rotation angle, the coordinates of the endpoints of the inner arc of one of the at least three arc-shaped discs most adjacent to the bolt connector after rotation of the articulated connector are calculated through the first conversion functions, the second conversion functions, the third conversion functions and the fourth conversion functions, and when a linear distance between the coordinates of one of the endpoints after rotation and the coordinates of the one of the endpoints is the smallest, a rotation angle of the articulated connectors on one side as a whole is the smallest.

7. A multi-disc quick coupler designed by the design method for a multi-disc quick coupler according to claim 1, comprising the clamp, the bolt connector and the articulated connector, the clamp is configured as the annular coupler formed by jointing the at least three arc-shaped discs, the clamp is of the axisymmetric structure as a whole, the articulated connector or the bolt connector is mounted between the adjacent arc-shaped discs of the at least three arc-shaped discs to connect the adjacent arc-shaped discs, the bolt connector is configured to connect two of the at least three arc-shaped discs, one of two ends of each of the at least three arc-shaped discs is provided with an ear plate for the bolt connector, the ear plate is configured with a kidney-shaped hole extending through the ear plate, an attachment bolt extends through the kidney-shaped hole, and a length direction of a kidney of the kidney-shaped hole is perpendicular to the central symmetry axis of the clamp.

8. The multi-disc quick coupler according to claim 7, wherein the articulated connector comprises rotary parts fixed to a respective one of the at least three arc-shaped discs and a connecting part hinged with the rotary parts, two of the rotary parts are provided corresponding to the adjacent arc-shaped discs of the at least three arc-shaped discs, two ends of the connecting part are respectively rotatably connected to the two of the rotary parts, each of the two of the rotary parts is a latch fixed at each of the two ends of a respective one of the at least three arc-shaped discs, the connecting part is a snap ring buckled on two adjacent latches, and the two adjacent latches are arranged in a shape of arcs facing away from each other, so that the adjacent arc-shaped discs of the at least three arc-shaped discs are rotatable with an edge of the snap ring as a rotation axis.

9. The multi-disc quick coupler according to claim 7, wherein the articulated connector comprises a pin assembly and a slot assembly, the pin assembly and the slot assembly are respectively fixed at one of the two ends of the adjacent arc-shaped discs, the pin assembly and the slot assembly at the two ends of the adjacent arc-shape discs cooperate with each other, the slot assembly comprises two first connecting arms with hinge slots, the hinge slots are defined on opposite sidewalls of the two first connecting arms, the hinge slots are offset to a side of the two first connecting arms away from a respective one of the adjacent arc-shaped discs and form pin mounting openings on the side of the two first connecting arms away from the respective one of the adjacent arc-shaped discs, the pin assembly is a second connecting arm with a hinge pin, the second connecting arm extends between the two first connecting arms, two ends of the second connecting arm are respectively provided with the hinge pin corresponding to a respective one of the hinge slots, and the hinge pin is configured to be inserted into the respective one of the hinge slots from a respective one of the pin mounting openings.

10. The multi-disc quick coupler according to claim 7, wherein the articulated connector comprises a pin assembly and a slot assembly, the pin assembly and the slot assembly are respectively fixed at one of the two ends of the adjacent arc-shaped discs fixed by the articulated connector, the pin assembly and the slot assembly of the adjacent arc-shaped discs cooperate with each other, the slot assembly comprises a first connecting arm with a hinge slot, the hinge slot is defined at a side of the first connecting arm facing the pin assembly, the hinge slot is offset to a side of the first connecting arm away from a respective one of the adjacent arc-shaped discs and forms a pin mounting opening on the side of the first connecting arm away from the respective one of the adjacent arc-shaped discs, the pin assembly is a second connecting arm with a hinge pin, the hinge pin is provided at a side of the pin assembly facing the slot assembly, and the hinge pin is configured to be inserted into the hinge slot from the pin mounting opening.
